(19) United States
(12) Patent Application Publication
(10) Pub. No.: US 2014/0346471 A1
(43) Pub. Date: Nov. 27, 2014

(54) STRUCTURE AND METHOD FOR PACKAGING ORGANIC PHOTOELECTRIC DEVICE

(71) Applicant: Wistron Corp., New Taipei City (TW)

(72) Inventors: Chi-Jen KAO, New Taipei City (TW); Tarng-Shiang HU, New Taipei City (TW); Yi-Kai WANG, New Taipei City (TW); Ko-Yu CHIANG, New Taipei City (TW)

(73) Assignee: Wistron Corp., New Taipei City (TW)

(21) Appl. No.: 14/188,831

(22) Filed: Feb. 25, 2014

(30) Foreign Application Priority Data
May 27, 2013 (TW) 102118664

(51) Int. Cl. H01L 51/44

(52) U.S. Cl. CPC H01L 51/448
USPC 257/40; 438/66

(57) ABSTRACT

A method for packaging an organic photoelectric device is disclosed. In the method, an inorganic substrate is provided, an organic layer is coated or pasted on the inorganic substrate to form a hybrid substrate. An organic photoelectric device is formed on the hybrid substrate, and the organic layer and the organic photoelectric device are patterned to define a package region. A permeation barrier layer is disposed on the package region to cover the organic photoelectric device.

### RELATED APPLICATIONS

This application claims priority to Taiwanese Application Serial Number 102118664, filed May 27, 2013, which is herein incorporated by reference.

### BACKGROUND

1. Field of Disclosure

The present disclosure relates to a package structure. More particularly, the present disclosure relates to the package structure of an organic photoelectric device.

2. Description of Related Art

Organic photoelectric devices are mostly composed of organic semiconductors. The organic photoelectric devices have been applied on various products such as organic light-emitting diodes, organic thin film transistors, and organic solar cells. In that organic semiconductor materials are very sensitive to moistures, oxygen and ultraviolet light, stacking or shielding of certain materials may prevent the organic semiconductor materials from damages caused by oxygen and UV rays. However, the moisture permeation of the organic semiconductor materials is still a serious problem to be overcome.

At present, flexible devices made from the organic photoelectric devices are usually flexible, light, thin, impact endurable, and bendable. If a Roll-to-Roll process is utilized in the manufacturing process of the flexible device, mass production can be realized, and the products are more competitive in price. However, the flexible devices become more vulnerable to be deteriorated by moisture due to the organic photoelectric devices. Therefore, paths of the moisture permeation need to be carefully managed in the package process. Conventionally, barrier layers are attached to top and bottom of the organic photoelectric devices to prevent the moisture intrusion, and such attaching method is very convenient and easy to be carried out, and mass production of the organic photoelectric device can be realized.

Due to the poor moisture blocking ability of the organic flexible substrate, an inorganic material layer is required to be coated thereon to isolate the moisture. However, even if the organic flexible substrate is coated with an inorganic material layer, the moisture blocking ability of the coated organic flexible substrate is still poorer than that of the metal material. The organic flexible substrate will be cracked or damaged after being bended for a period of time. As such, the reliability of the organic photoelectric devices is significantly reduced, and the mass production is hard to be realized.

### SUMMARY

According to one embodiment of the present disclosure, a method for packaging an organic photoelectric device is disclosed. In the method, an inorganic substrate is provided, an organic layer is coated or pasted on the inorganic substrate to form a hybrid substrate. An organic photoelectric device is formed on the hybrid substrate, and the organic layer and the organic photoelectric device are patterned to define a package region. A permeation barrier layer is disposed on the package region to cover the organic photoelectric device.

According to another embodiment of the present disclosure, a structure for packaging an organic photoelectric device is disclosed. The structure includes an inorganic substrate, an organic layer, an organic photoelectric device, and a permeation barrier layer. The organic layer is disposed on the inorganic substrate. The organic photoelectric device is disposed on the organic layer, in which cross-sectional areas of the organic photoelectric device and the organic layer is small than a cross-sectional area of the inorganic substrate. The permeation barrier layer is disposed on the organic photoelectric device and covering the organic photoelectric device as well as the organic layer, in which the permeation barrier layer also contacts with the inorganic substrate.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A to FIG. 1D are cross-sectional views of a structure for packaging an organic photoelectric device during a manufacturing process according to a first embodiment of the present disclosure;

FIG. 1E is a top view of the structure for packaging the organic photoelectric device during the manufacturing process according to the first embodiment of the present disclosure;

FIG. 2A is a diagram of a structure for packaging the organic photoelectric device during a Roll-to-Roll manufacture process according to a second embodiment of the present disclosure;

FIG. 2B is a top view of the structure for packaging the organic photoelectric device during the Roll-to-Roll manufacture process according to the second embodiment of the present disclosure;

FIG. 2C is a cross-sectional structure diagram of a permeation barrier layer according to the second embodiment of the present disclosure;

FIG. 3A to FIG. 3E are cross-sectional structure diagrams of an organic photoelectric device during a manufacturing process according to a third embodiment of the present disclosure; and

FIG. 4A to FIG. 4C are current-voltage curve diagram of the organic photoelectric devices.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

The structure and method for packaging the organic photoelectric device of the following embodiment define a patterned region through a laser ablation process, and a permeation barrier layer is disposed on the patterned region to cover the surface and sides of the organic photoelectric device. Therefore, the moisture permeation problem is solved and the component life can be prolonged. Particularly, the moisture can hardly enter the organic photoelectric devices through the sides of the organic photoelectric devices, and the property of the organic photoelectric device is more reliable. In addition, the method for packaging is compatible with the Roll-to-Roll process, which is proper for mass production.

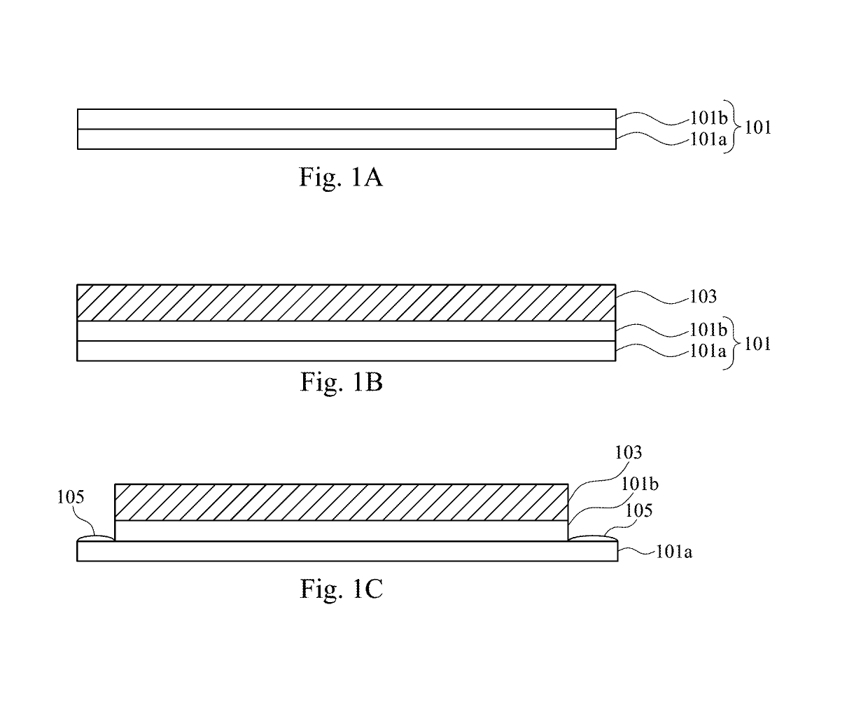

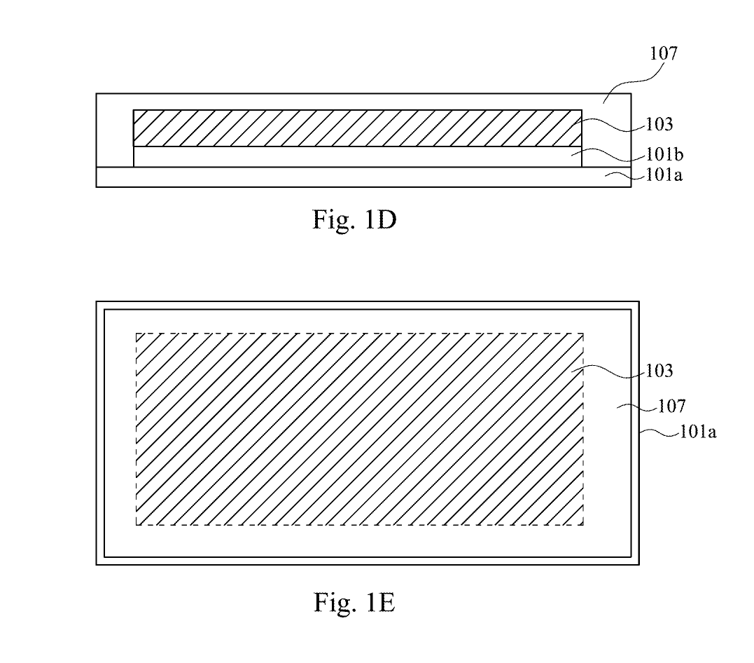

FIG. 1A to FIG. 1D are cross-sectional views of a structure for packaging an organic photoelectric device during a manufacturing process according to a first embodiment of the present disclosure, and FIG. 1E is a top view of the structure for packaging the organic photoelectric device during the manufacturing process according to the first embodiment of the present disclosure. In the method for packaging the organic photoelectric device, an inorganic substrate 101a is provided. The inorganic substrate 101a can be made of a thin and Rollable metal material, such as aluminum, iron, or stainless steel which has better property against water and oxygen, and this material can provide better moisture resistant property. Next, an organic layer 101b is coated or pasted on the inorganic substrate 101a to form a hybrid substrate, which means the hybrid substrate 101 is mainly composed of the inorganic substrate 101a combined with the organic layer 101b (FIG. 1A). The organic layer 101b can be made of solidified organic material, such as Polyimide (PI), Acrylic, Epoxy, or a hard coating material, which can be pasted, coated, or evaporated, such that the organic layer 101b can be pasted or coated on the inorganic substrate 101a, and the inorganic substrate 101a is electrically insulated from other material layers. With the organic layer 101b, the organic photoelectric device can be disposed thereon. Because the organic photoelectric device is not directly disposed on the inorganic substrate 101a but through the organic layer 101b, heterojunction problem can be avoided. The coating method substantially includes the physical vapor deposition (PVD) and the chemical vapor deposition (CVD). The PVD method can be the Vacuum evaporation deposition method or the Plasma sputtering, and the chemical vapor deposition method can be the low-pressure CVD or the direct liquid injection CVD. However, the present disclosure shall not be limited by these methods.

After the forming of the hybrid substrate 101, the organic photoelectric device 103 is subsequently formed on the hybrid substrate 101 (FIG. 1B), such as the organic light-emitting diodes, the organic thin film transistors, and the organic solar cells. Specifically, the organic photoelectric device 103 can be formed on the hybrid substrate 101 by a Roll-to-Roll Lithography process.

After the organic photoelectric device 103 is formed, the organic layer 101b and the organic photoelectric device 103 are patterned to define a package region 105 (FIG. 1C). In more detail, the organic layer 101b and the organic photoelectric device 103 are patterned through a Roll-to-Roll laser ablation process, in which a gas laser, a solid laser, a semiconductor laser, or a liquid laser can be used as a source to perform the Roll-to-Roll laser ablation process. Because the Roll-to-Roll laser ablation process can merely etch the organic layer 101b and the organic photoelectric device 103 and can not affect the inorganic substrate 101a, therefore, part of the inorganic substrate 101a, that is, the package region 105, is exposed.

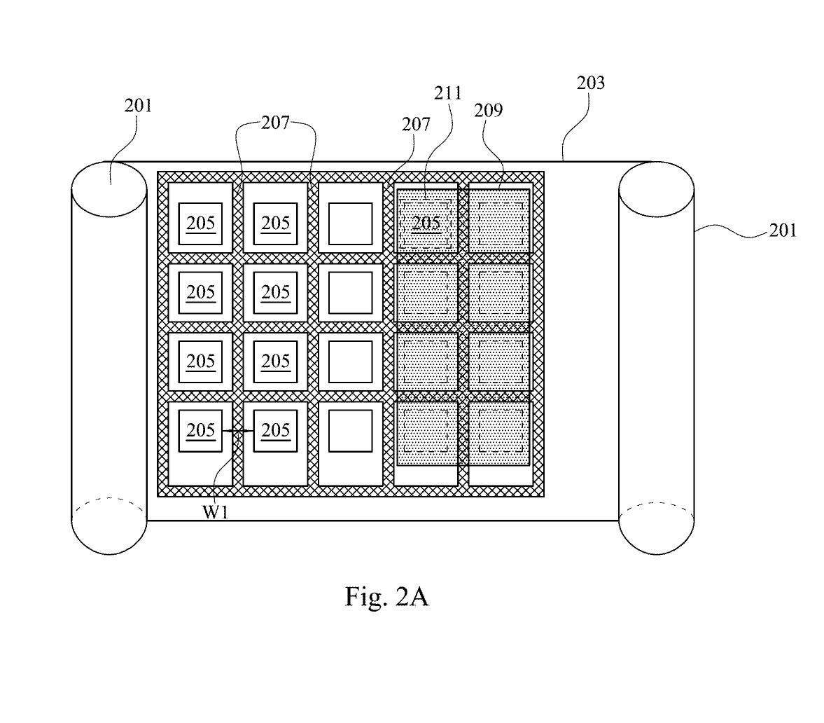

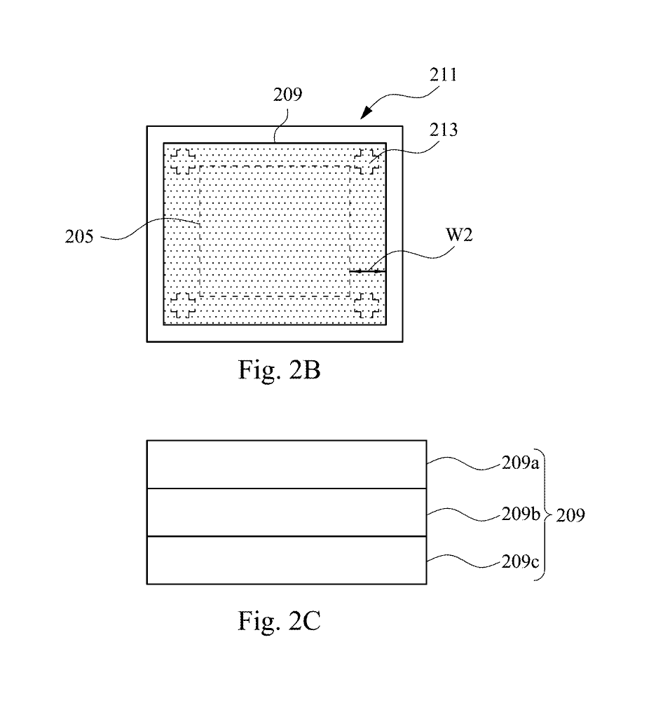

When the package region 105 has been defined, a permeation barrier layer 107 is disposed on the package region 105 through a Roll-to-Roll Lamination process (FIG. 1D). In more detail, a moisture permeation barrier film which includes a back adhesive layer can be used as the permeation barrier layer 107. The permeation barrier layer 107 can be an organic material layer, an inorganic material layer, or a multi-layer structure composed of the organic-inorganic compound layers. To further improve the ability to resist the water and the oxygen, the permeation barrier layer 107 can also be formed by repeatedly stacking the organic material layers and the inorganic material layers. The back adhesive layer is disposed on the other side of the organic material layer for attaching the permeation barrier layer 107 to the organic photoelectric device 103. The back adhesive layer can be made of thermoset material or thermoplastic material such as Acrylic or Epoxy which can be heated and pressed to perform the attaching. Generally, the organic material layer can be a high transmittance polymer film (such as: PET, PC, PEN, etc.), and the inorganic material layer can be made of an inorganic transparent material such as polyvinylidene fluoride (PVDF), aluminum oxide (Al₂O₃), zirconium oxide (ZrO₂) which are resistant to water and oxygen. The inorganic material layer can be produced by coating, pasting, a PVD process or a CVD process. The cross-sectional structure of the permeation barrier layer 107 is shown in FIG. 2C.

The permeation barrier layer 107 covers the organic layer 101b as well the organic photoelectric device 103, which means that the top surface of the organic photoelectric device 103 and the sides of the organic photoelectric device 103 as well as the organic layer 101b are not exposed to the environment but are covered by the permeation barrier layer 107. As a result, the moisture is prevented from damaging the organic photoelectric device 103 and the organic layer 101b. The package structure is shown in FIG. 1D.

FIG. 1E is a top view of the structure for packaging the organic photoelectric device during the manufacturing process according to the first embodiment of the present disclosure. As shown in the top view, a cross-sectional area of the permeation barrier layer 107 is greater than the cross-sectional area of the organic photoelectric device 103 but is substantially equal to the cross-sectional area of the inorganic substrate 101a. Thus, the entire organic photoelectric device 103 is covered with the permeation barrier layer 107 and is prevented from being damaged by the moisture.

FIG. 2A to FIG. 2C are diagrams of a structure for packaging the organic photoelectric device during a Roll-to-Roll manufacture process according to a second embodiment of the present disclosure. A Roll-to-roll process is highly efficient and can perform the production continuously, it is generally applied on flexible material, such as films, plastics, or stainless steel sheets. In addition, metal substrates which are thin enough (thickness of about <200 um) can serve in the Roll-to-Roll process, such as aluminum foils, copper foils and so on. As the metal substrate is getting wider, more organic photoelectric devices can be contained in each length unit. After the substrate 203 is unwound from the roller 201, organic photoelectric devices 205 are set on the substrate 203. In the Roll-to-Roll process, the manufacturing of the organic photoelectric devices 205 depends on the materials and kinds of processes. The Roll-to-Roll process is substantially applied on the patterning lithography steps such as the coating step, photo-resister disposing step, exposure step, etching step, and the photo-resister removing step, to produce the organic photoelectric devices.

Then, a laser ablation process is performed for patterning in order to remove the organic layers and to expose the inorganic material 207. The size of the patterned region by laser ablation is related to the layout arrangement of the organic photoelectric devices. The surrounding of the organic photoelectric devices 205 which requires packaging is patterned, the distance W1 between the organic photoelectric devices 205 is greater than 1 mm, and the organic photoelectric devices 205 are separated by the inorganic material 207 disposed therein.

The alignment and lamination process is subsequently performed to dispose the permeation barrier layer 209 for blocking the moisture from entering the organic photoelectric devices 205. As shown in the regional block 211 of FIG. 2B, the alignment marks 213 are disposed on the surroundings of the organic photoelectric devices 205, such that the permeation barrier layer 209 can be aligned. The distance W2 between the edge of the permeation barrier layer 209 and the edge of the organic photoelectric devices 205 is greater than 3 mm. Proper temperature and pressure are selected according to the property of the back adhesive layer of the permeation barrier layer 209 to attach the permeation barrier layer 209 thereon. In detail, the attachment is performed by a mechanical arm combined with an automatic image alignment system, such as a charge-coupled device (CCD). As shown in FIG. 2C, the permeation barrier layer 209 is substantially composed of three material layers, that is, the inorganic material layer 209a, the organic material layer 209b, and the back adhesive layer 209c.

When the alignment and lamination process have been done, the roller 201 begins to rewind.

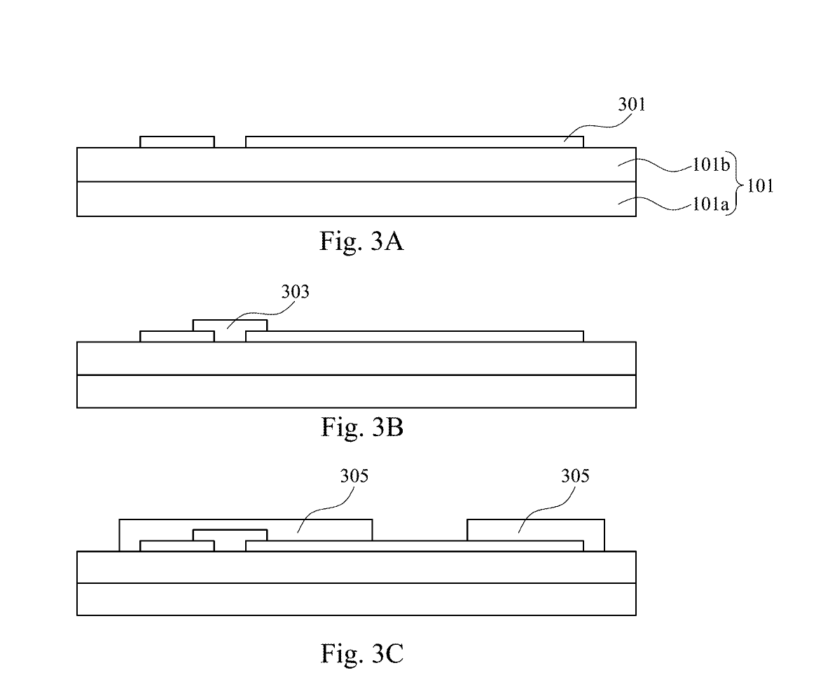

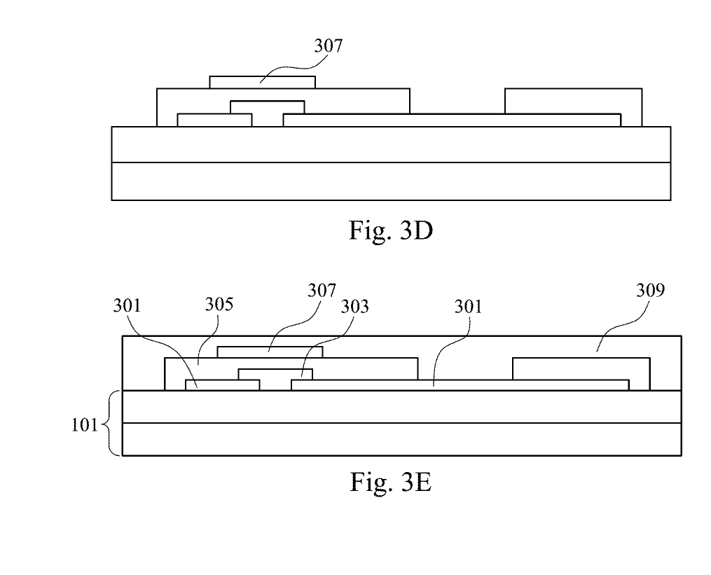

FIG. 3A to FIG. 3E are cross-sectional structure diagrams of an organic photoelectric device during a manufacturing process according to a third embodiment of the present disclosure. In the manufacturing of the organic photoelectric devices, a metal layer 301, a semiconductor layer 303, a dielectric layer 305, a gate layer 307, and an intermediate layer 309 are sequentially stacked on a hybrid substrate 101. In other words, the semiconductor layer 303 is disposed on the metal layer 301; the dielectric layer 305 is disposed on the semiconductor layer 303; the gate layer 307 is disposed on the dielectric layer 305; and the intermediate layer 309 is disposed on the gate layer 307. Particularly, the intermediate layer 309 covers each layer of the organic photoelectric device and contacts with the hybrid substrate 101.

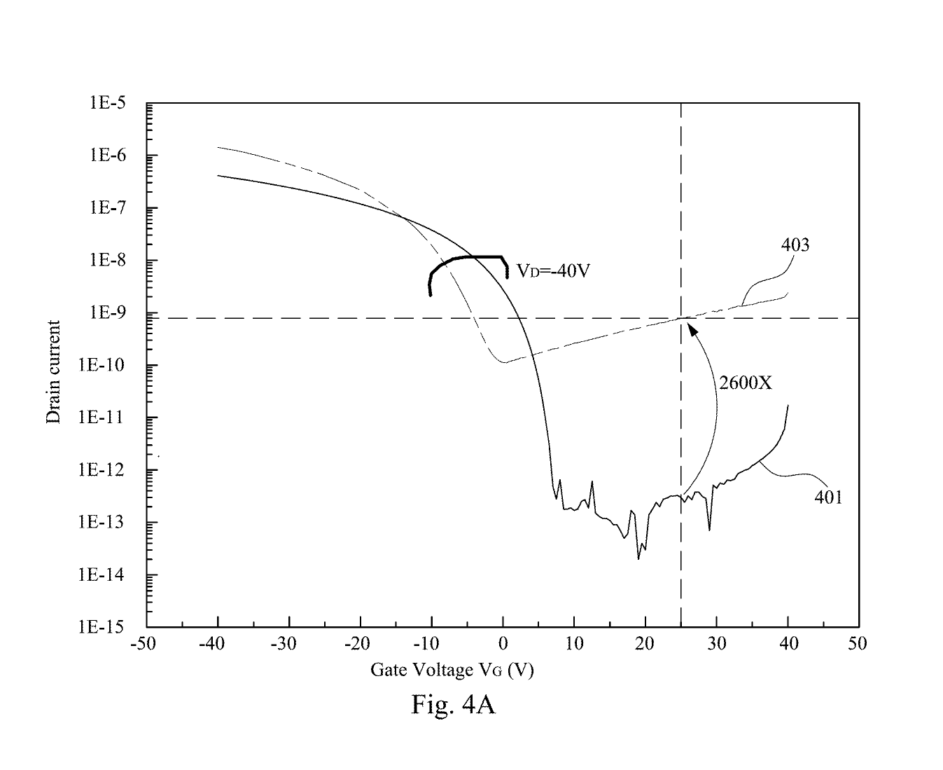

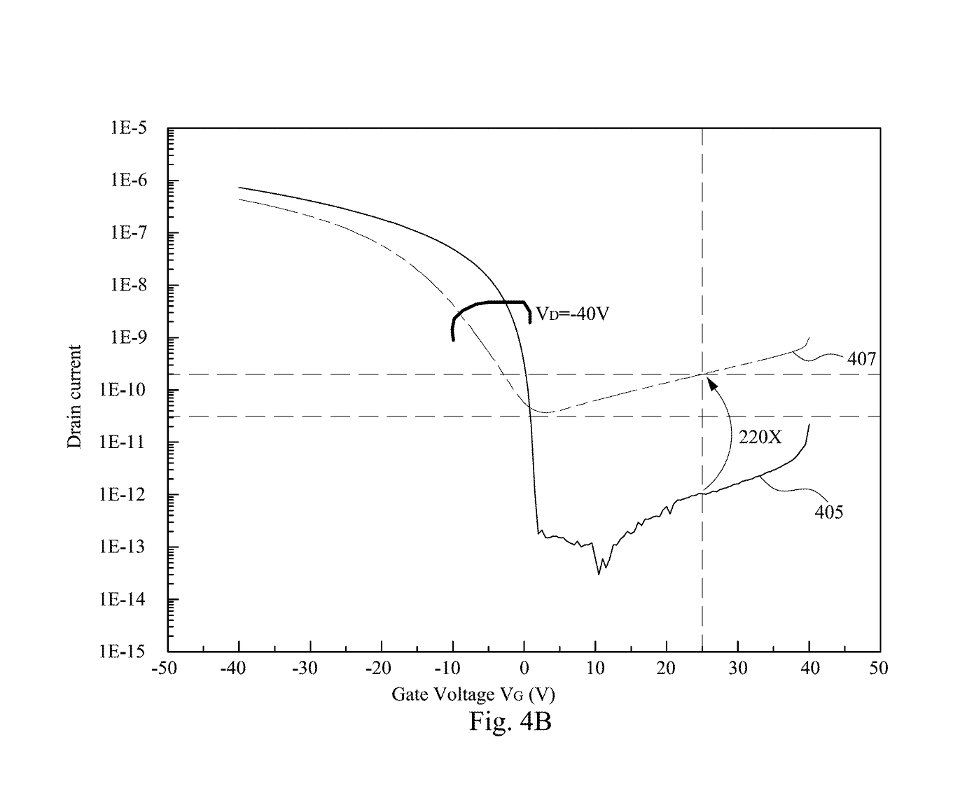

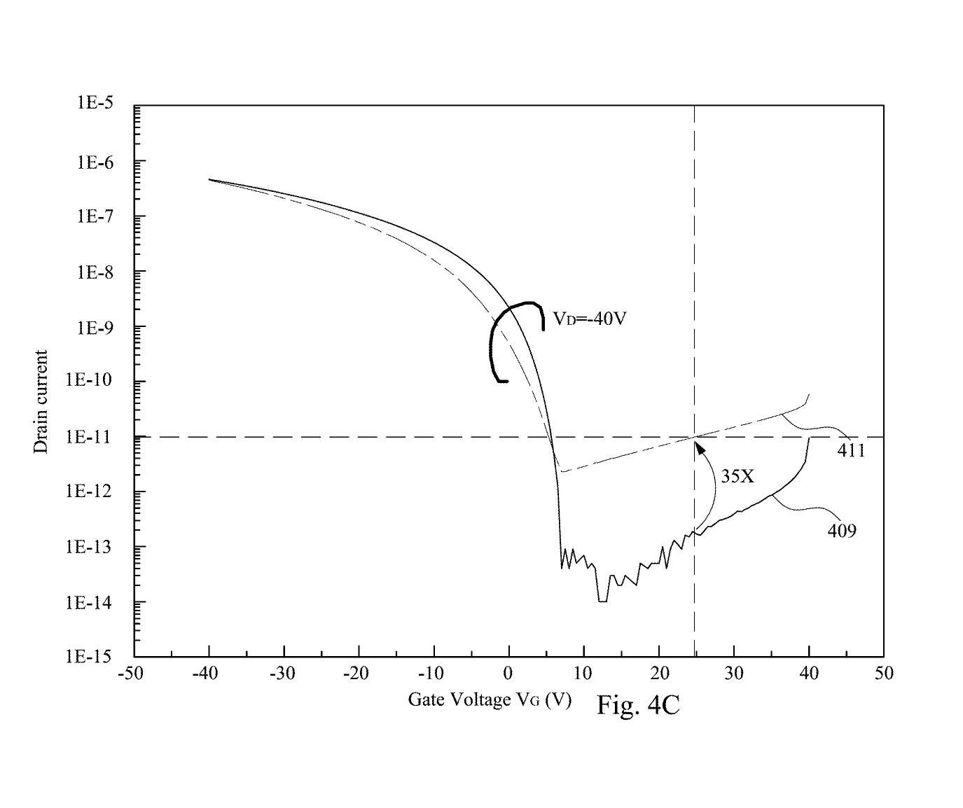

FIG. 4A to FIG. 4C are current-voltage curve diagram of the organic photoelectric devices. FIG. 4A presents the current-voltage curve of the organic photoelectric device without the permeation barrier layer, in which curve 401 presents the original current-voltage characteristic while curve 403 represents current-voltage characteristics of an aging test under moisture environment (60° C., 85 RH %). Comparing the curve 401 and curve 403, the threshold voltage of the organic photoelectric device under moisture environment is shifted and the leakage current increases. The leakage current in the moisture environment at V_{G} 25 v is 2600 times of that in the original state. That is, the transistor characteristic in the moisture environment differs a lot from the original state.

FIG. 4B presents the current-voltage curve diagram of an organic photoelectric device with an permeation barrier layer disposed thereon, however, the laser ablation process is not taken for patterning, and the sides of the organic photoelectric device are not packaged. The curve 405 presents the original current-voltage characteristic while curve 407 represents current-voltage characteristics in the aging test under the moisture environment (60° C., 85 RH %). By comparing the curve 405 and curve 407, it can be realized the amounts of the threshold voltage shift and the leakage current are reduced. However, the leakage current in the moisture environment at V_{G} 25 v is still 220 times of that in the original state. That is, the transistor characteristics in the moisture environment are still quite different from the original state.

FIG. 4C presents the current-voltage curve diagram of the organic photoelectric device with the permeation barrier layer disposed thereon. Particularly, the laser ablation process has been taken for patterning, and the sides of the organic photoelectric device have been packaged. The curve 409 presents the original current-voltage characteristic while curve 411 represents the current-voltage characteristics of the aging test under the moisture environment (60° C., 85 RH %). By comparing the curve 409 and curve 411, it can be realized that the amounts of the threshold voltage shift and the leakage current are reduced a lot. The leakage current in the moisture environment at V_{G} 25 v is merely 35 times of that in the original state, and the transistor characteristics in the moisture environment meet the corresponding requirements.

The structure and method for packaging the organic photoelectric device of the above embodiments define a patterned region through the laser ablation process, and a permeation barrier layer is disposed on the patterned region to cover the surface and sides of the organic photoelectric device. Therefore, the moisture permeation problem is solved. Particularly, the moisture is blocked from entering the organic photoelectric devices through the sides, and the property of the organic photoelectric device is more reliable. In addition, the method for packaging is compatible with the Roll-to-Roll process, which is proper for mass production.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method for packaging an organic photoelectric device, the method comprising:
providing an inorganic substrate;
coating or pasting an organic layer on the inorganic substrate to form a hybrid substrate;
forming an organic photoelectric device on the hybrid substrate;
patterning the organic layer and the organic photoelectric device to define a package region; and
disposing a permeation barrier layer on the package region to cover the organic photoelectric device.

2. The method of claim 1, wherein a surface and a plurality of sides of the organic photoelectric device is covered with the permeation barrier layer.

3. The method of claim 1, wherein patterning the organic layer and the organic photoelectric device is performed through a Roll-to-Roll Lithography process.

4. The method of claim 1, wherein patterning the organic layer and the organic photoelectric device is performed through a Roll-to-Roll laser ablation process.

5. The method of claim 4, wherein the Roll-to-Roll laser ablation process is performed with a gas laser, a solid laser, a semiconductor laser, or a liquid laser.

6. The method of claim 4, wherein the organic layer is made of a Polyimide, an Acrylic, or an Epoxy.

7. The method of claim 4, wherein patterning the organic layer and the organic photoelectric device is performed to expose part of the inorganic substrate.

8. The method of claim 1, wherein disposing the permeation barrier layer is performed on the package region through a Roll-to-Roll Lamination process.

9. The method of claim 1, wherein a moisture permeation barrier film which comprises a back adhesive layer is used as the permeation barrier layer.

10. The method of claim 1, wherein the permeation barrier layer covers the organic layer and the organic photoelectric device.

11. The method of claim 1, wherein the inorganic substrate is made of a thin and Rollable metal material.

12. A structure for packaging an organic photoelectric device, the structure comprising:
an inorganic substrate;
an organic layer disposed on the inorganic substrate;
an organic photoelectric device disposed on the organic layer, wherein cross-sectional areas of the organic photoelectric device and the organic layer is small than a cross-sectional area of the inorganic substrate; and
a permeation barrier layer, disposed on the organic photoelectric device, covering the organic photoelectric device and the organic layer, wherein the permeation barrier layer contacts with the inorganic substrate.

13. The structure as claimed in claim 12, wherein a thickness of the inorganic substrate is less than 200 um.

14. The structure as claimed in claim 12, wherein the organic photoelectric device comprises:
a metal layer;
a semiconductor layer disposed on the metal layer;
a dielectric layer disposed on the semiconductor layer;
a gate layer disposed on the dielectric layer; and
an intermediate layer disposed on the gate layer.

15. The structure as claimed in claim 12, wherein the organic layer is made of a Polyimide, an Acrylic, or an Epoxy.

16. The structure as claimed in claim 12, wherein the permeation barrier layer is made of a moisture permeation barrier film which comprises a back adhesive layer.

17. The structure as claimed in claim 12, wherein the permeation barrier layer is a material selected from the group consisting of an organic material layer, an inorganic material layer, and an organic-inorganic compound layer.

18. The structure as claimed in claim 12, wherein the permeation barrier layer comprises:
an inorganic material layer;
an organic material layer in contact with and attached to the inorganic material layer; and
a back adhesive layer having a surface in contacting with and attached to the organic material layer.

19. The structure as claimed in claim 12, wherein the inorganic substrate is made of a thin and Rollable metal material.

20. The structure as claimed in claim 12, wherein the inorganic substrate is made of aluminum, iron, copper, or stainless steel.
